(19) United States
(12) Patent Application Publication
(10) Pub. No.: US 2002/0175370 A1
(43) Pub. Date: Nov. 28, 2002

(54) Hybrid semiconductor field effect structures and methods

(75) Inventor: David E. Bockelman, Dripping Springs, TX (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/861,638

(22) Filed: May 22, 2001

(51) Int. Cl. H01L 29/76; H01L 29/94; H01L 31/062; H01L 31/113; H01L 31/119

(52) U.S. Cl. 257/344

(57) ABSTRACT

A hybrid semiconductor structure is provided. The structure may comprise a field effect transistor that may include a back gate. The back gate for a non-compound semiconductor field effect transistor may be formed by providing a contact (506, 550) over a compound semiconductor region before forming an insulating layer (205, 508, 542, 1161) and before forming the body of the field effect transistor over the compound semiconductor region. If desired, a contact (528, 544) for a back gate may also be formed after the body of the non-compound semiconductor field effect transistor is formed by forming a trench (526, 548) and depositing the contact (528, 544) in the trench (526, 548). In forming the back gate, the insulating layer (205, 508, 542, 1161) may be used as an etch-stop.

### FIELD OF THE INVENTION

This invention relates generally to semiconductor structures and devices and to a method for their fabrication, and more specifically to field effect transistors in hybrid semiconductor structures.

### BACKGROUND OF THE INVENTION

The vast majority of semiconductor discrete devices and integrated circuits are fabricated from silicon, at least in part because of the availability of inexpensive, high quality monocrystalline silicon substrates. Other semiconductor materials, such as the so called compound semiconductor materials, have physical attributes, including wider bandgap and/or higher mobility than silicon, or direct bandgaps that makes these materials advantageous for certain types of semiconductor devices. Unfortunately, compound semiconductor materials are generally much more expensive than silicon and are not available in large wafers as is silicon. Gallium arsenide (GaAs), the most readily available compound semiconductor material, is available in wafers only up to about 150 millimeters (mm) in diameter. In contrast, silicon wafers are available up to about 300 mm and are widely available at 200 mm. The 150 mm GaAs wafers are many times more expensive than are their silicon counterparts. Wafers of other compound semiconductor materials are even less available and are more expensive than GaAs.

However, compound semiconductor materials have desirable characteristics that make them useful for certain types of applications. On the other hand, silicon or other non-compound semiconductor materials are more useful for other types of applications, and it is sometimes desirable to have a single device with some of its circuitry made in silicon and some of its circuitry made in a compound semiconductor material such as GaAs.

In addition, it is frequently desirable to use very large scale integration (VLSI) techniques to manufacture very large scale integrated circuits including field effect transistors that have back gates. Such techniques are techniques that are used to cost-effectively manufacture high density integrated circuit structures. However, such known techniques have been deficient in providing cost-effective high density integrated circuits that include field effect transistors having back gates. It is also sometimes desirable to have very large scale integrated circuits that integrate circuitry in a compound semiconductor material with circuitry, such as field effect transistors with back gates in another semiconductor material on the same die.

Accordingly, a need exists for cost-effective and large scale integrated circuits that have back gates for some of the devices in the circuit.

### BRIEF DESCRIPTION OF THE DRAWINGS

FIGS. 1, 2, 3, 24, 25 illustrate schematically, in cross section, device structures that can be used in accordance with various embodiments of the invention.

FIG. 4 illustrates graphically the relationship between maximum attainable film thickness and lattice mismatch between a host crystal and a grown crystalline overlayer.

FIG. 5 is a high resolution Transmission Electron Micrograph (TEM) of illustrative semiconductor material manufactured in accordance with what is shown herein.

FIG. 6 is an x-ray diffraction taken on an illustrative semiconductor structure manufactured in accordance with what is shown herein.

FIG. 7 illustrates a high resolution Transmission Electron Micrograph of a structure including an amorphous oxide layer.

FIG. 8 illustrates an x-ray diffraction spectrum of a structure including an amorphous oxide layer.

FIGS. 9-12 illustrate schematically, in cross-section, the formation of a device structure in accordance with another embodiment of the invention.

FIGS. 13-16 illustrate a probable molecular bonding structure of the device structures illustrated in FIGS. 9-12.

FIGS. 17-20 illustrate schematically, in cross-section, the formation of a device structure in accordance with still another embodiment of the invention.

FIGS. 21-23 illustrate schematically, in cross section, the formation of a yet another embodiment of a device structure in accordance with the invention.

FIGS. 26-30 include illustrations of cross-sectional views of a portion of an integrated circuit that includes a compound semiconductor portion, a bipolar portion, and an MOS portion in accordance with what is shown herein.

FIG. 31 shows a cross-sectional view of a hybrid semiconductor structure including silicon semiconductor islands on a compound semiconductor substrate.

FIGS. 32 and 33 show a cross-sectional and a plan view, respectively, of a hybrid semiconductor structure including silicon semiconductor islands in a compound semiconductor substrate.

FIG. 34 shows an intermediate step in the formation of the hybrid structure of FIGS. 32 and 33.

FIG. 35 shows a further optional processing step in the formation of the hybrid structure of FIGS. 32 and 33.

FIG. 36 shows a cross-sectional view of a portion of an integrated circuit that includes a compound semiconductor portion and an MOS portion in accordance with what is shown herein.

FIGS. 37-41 show cross-sectional views of the formation of a portion of an integrated circuit comprising a hybrid transistor with a back gate in accordance with the present invention.

FIGS. 42-44 show cross-sectional views of the formation of a portion of an integrated circuit comprising a hybrid transistor with a back gate in accordance with the present invention.

FIGS. 45-46 show cross-sectional views of the formation of a portion of an integrated circuit comprising a hybrid transistor with a back gate in accordance with the present invention.

FIGS. 47-49 show cross-sectional views of the formation of a portion of an integrated circuit comprising a hybrid transistor with a back gate in accordance with the present invention.

FIG. 50 is a flow chart of illustrative steps involved in one way of forming a field effect transistor with a back gate in accordance with the present invention.

FIG. 51 is a flow chart of illustrative steps involved in another way of forming a field effect transistor with a back gate in accordance with the present invention.

FIG. 52 is a flow chart of illustrative steps involved in operating a field effect transistor with a back gate in accordance with the present invention.

Skilled artisans will appreciate that in many cases elements in certain FIGs. are illustrated for simplicity and clarity and have not necessarily been drawn to scale. For example, the dimensions of some of the elements in certain FIGs. may be exaggerated relative to other elements to help to improve understanding of what is being shown.

### DETAILED DESCRIPTION OF THE DRAWINGS

The present invention involves semiconductor structures of particular types. For convenience herein, these semiconductor structures are sometimes referred to as “composite semiconductor structures” or “composite integrated circuits” because they include two (or more) significantly different types of semiconductor devices in one integrated structure or circuit. For example, one of these two types of devices may be silicon-based devices such as CMOS devices, and the other of these two types of devices may be compound semiconductor devices such GaAs devices. Illustrative composite semiconductor structures and methods for making such structures are disclosed in Ramdani et al. U.S. patent application Ser. No. 09/502,023, filed Feb. 10, 2000, which is hereby incorporated by reference herein in its entirety. Certain material from that reference is substantially repeated below to ensure that there is support herein for references to composite semiconductor structures and composite integrated circuits.

FIG. 1 illustrates schematically, in cross section, a portion of a semiconductor structure 20 which may be relevant to or useful in connection with certain embodiments of the present invention. Semiconductor structure 20 includes a monocrystalline substrate 22, accommodating buffer layer 24 comprising a monocrystalline material, and a layer 26 of a monocrystalline compound semiconductor material. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment, structure 20 also includes an amorphous intermediate layer 28 positioned between substrate 22 and accommodating buffer layer 24. Structure 20 may also include a template layer 30 between accommodating buffer layer 24 and compound semiconductor layer 26. As will be explained more fully below, template layer 30 helps to initiate the growth of compound semiconductor layer 26 on accommodating buffer layer 24. Amorphous intermediate layer 28 helps to relieve the strain in accommodating buffer layer 24 and by doing so, aids in the growth of a high crystalline quality accommodating buffer layer 24.

Substrate 22, in accordance with one embodiment, is a monocrystalline semiconductor wafer, preferably of large diameter. The wafer can be of a material from Group IV of the periodic table, and preferably a material from Group IVA. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate 22. In accordance with one embodiment, amorphous intermediate layer 28 is grown on substrate 22 at the interface between substrate 22 and the growing accommodating buffer layer 24 by the oxidation of substrate 22 during the growth of layer 24. Amorphous intermediate layer 28 serves to relieve strain that might otherwise occur in monocrystalline accommodating buffer layer 24 as a result of differences in the lattice constants of substrate 22 and buffer layer 24. As used herein, lattice constant refers to the distance between atoms of a cell measured in the plane of the surface. If such strain is not relieved by amorphous intermediate layer 28, the strain may cause defects in the crystalline structure of accommodating buffer layer 24. Defects in the crystalline structure of accommodating buffer layer 24, in turn, would make it difficult to achieve a high quality crystalline structure in monocrystalline compound semiconductor layer 26.

Accommodating buffer layer 24 is preferably a monocrystalline oxide or nitride material selected for its crystalline compatibility with underlying substrate 22 and with overlying compound semiconductor material 26. For example, the material could be an oxide or nitride having a lattice structure matched to substrate 22 and to the subsequently applied semiconductor material 26. Materials that are suitable for accommodating buffer layer 24 include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for accommodating buffer layer 24. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitride may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The compound semiconductor material of layer 26 can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. Suitable template 30 materials chemically bond to the surface of the accommodating buffer layer 24 at selected sites and provide sites for the nucleation of the epitaxial growth of the subsequent compound semiconductor layer 26. Appropriate materials for template 30 are discussed below.

FIG. 2 illustrates, in cross section, a portion of a semiconductor structure 40 in accordance with a further embodiment. Structure 40 is similar to the previously described semiconductor structure 20 except that an additional buffer layer 32 is positioned between accommodating buffer layer 24 and layer of monocrystalline compound semiconductor material 26. Specifically, additional buffer layer 32 is positioned between the template layer 30 and the overlying layer 26 of compound semiconductor material. Additional buffer layer 32, formed of a semiconductor or compound semiconductor material, serves to provide a lattice compensation when the lattice constant of accommodating buffer layer 24 cannot be adequately matched to the overlying monocrystalline compound semiconductor material layer 26.

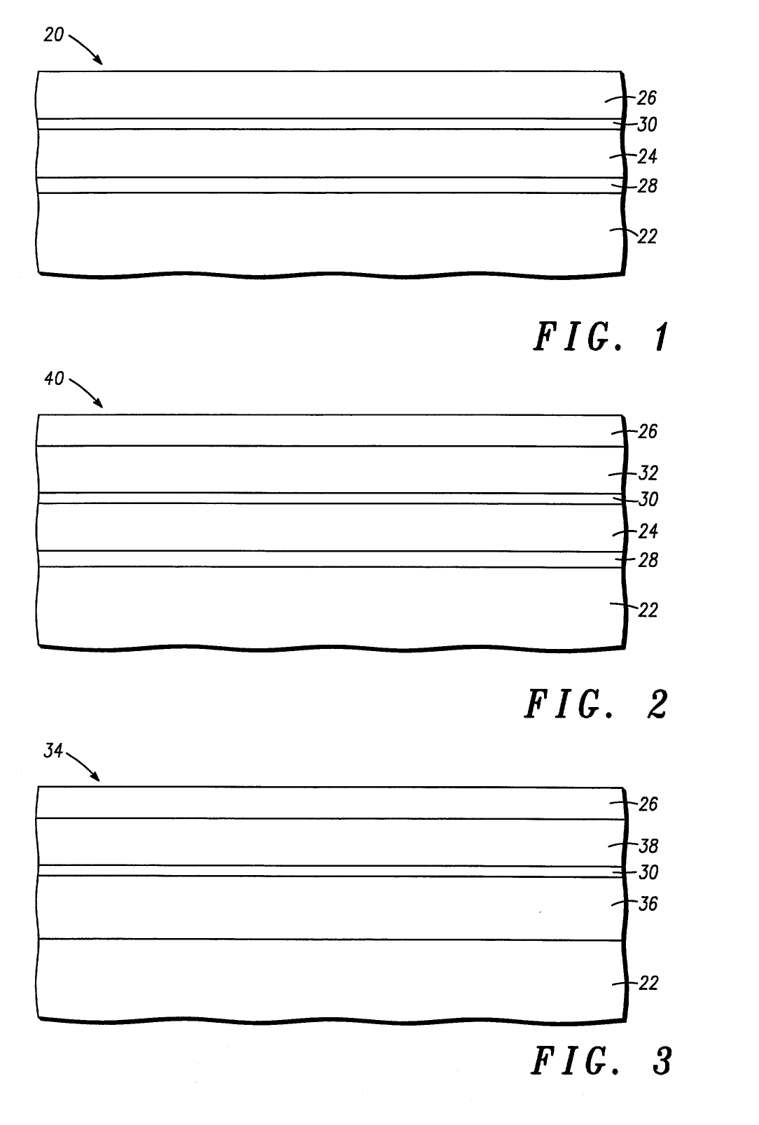

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional semiconductor layer 38.

As explained in greater detail below, amorphous layer 36 may be formed by first forming an accommodating buffer layer and an amorphous interface layer in a similar manner to that described above. Monocrystalline semiconductor layer 26 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and semiconductor layer 38 (subsequent to layer 38 formation) relieves stresses between layers 22 and 38 and provides a true compliant substrate for subsequent processing—e.g., compound semiconductor layer 26 formation.

The processes previously described above in connection with FIGS. 1 and 2 are adequate for growing monocrystalline compound semiconductor layers over a monocrystalline substrate. However, the process described in connection with FIG. 3, which includes transforming a monocrystalline accommodating buffer layer to an amorphous oxide layer, may be better for growing monocrystalline compound semiconductor layers because it allows any strain in layer 26 to relax.

Semiconductor layer 38 may include any of the materials described throughout this application in connection with either of compound semiconductor material layer 26 or additional buffer layer 32. For example, layer 38 may include monocrystalline Group IV or monocrystalline compound semiconductor materials.

In accordance with one embodiment of the present invention, semiconductor layer 38 serves as an anneal cap during layer 36 formation and as a template for subsequent semiconductor layer 26 formation. Accordingly, layer 38 is preferably thick enough to provide a suitable template for layer 26 growth (at least one monolayer) and thin enough to allow layer 38 to form as a substantially defect free monocrystalline semiconductor compound.

In accordance with another embodiment of the invention, semiconductor layer 38 comprises compound semiconductor material (e.g., a material discussed above in connection with compound semiconductor layer 26) that is thick enough to form devices within layer 38. In this case, a semiconductor structure in accordance with the present invention does not include compound semiconductor layer 26. In other words, the semiconductor structure in accordance with this embodiment only includes one compound semiconductor layer disposed above amorphous oxide layer 36.

The layer formed on substrate 22, whether it includes only accommodating buffer layer 24, accommodating buffer layer 24 with amorphous intermediate or interface layer 28, or an amorphous layer such as layer 36 formed by annealing layers 24 and 28 as described above in connection with FIG. 3, may be referred to generically as an “accommodating layer.”

The following non-limiting, illustrative examples illustrate various combinations of materials useful in structures 20, 40 and 34 in accordance with various alternative embodiments. These examples are merely illustrative, and it is not intended that the invention be limited to these illustrative examples.

### EXAMPLE 1

In accordance with one embodiment, monocrystalline substrate 22 is a silicon substrate oriented in the (100) direction. Silicon substrate 22 can be, for example, a silicon substrate as is commonly used in making complementary metal oxide semiconductor (CMOS) integrated circuits having a diameter of about 200-300 mm. In accordance with this embodiment, accommodating buffer layer 24 is a monocrystalline layer of Sr_{z}Ba_{1-z}TiO₃ where z ranges from 0 to 1 and amorphous intermediate layer 28 is a layer of silicon oxide (SiOₓ) formed at the interface between silicon substrate 22 and accommodating buffer layer 24. The value of z is selected to obtain one or more lattice constants closely matched to corresponding lattice constants of the subsequently formed layer 26. Accommodating buffer layer 24 can have a thickness of about 2 to about 100 nanometers (nm) and preferably has a thickness of about 10 nm. In general, it is desired to have an accommodating buffer layer 24 thick enough to isolate compound semiconductor layer 26 from substrate 22 to obtain the desired electrical and optical properties. Layers thicker than 100 nm usually provide little additional benefit while increasing cost unnecessarily; however, thicker layers may be fabricated if needed. The amorphous intermediate layer 28 of silicon oxide can have a thickness of about 0.5-5 nm, and preferably a thickness of about 1.5-2.5 nm.

In accordance with this embodiment, compound semiconductor material layer 26 is a layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer 30 is formed by capping the oxide layer. Template layer 30 is preferably 1-10 monolayers of Ti—As, Sr—O—As, Sr—Ga—O, or Sr—Al—O. By way of a preferred example, 1-2 monolayers 30 of Ti—As or Sr—Ga—O have been shown to successfully grow GaAs layers 26.

### EXAMPLE 2

In accordance with a further embodiment, monocrystalline substrate 22 is a silicon substrate as described above. Accommodating buffer layer 24 is a monocrystalline oxide of strontium or barium zirconate or hafnate in a cubic or orthorhombic phase with an amorphous intermediate layer 28 of silicon oxide formed at the interface between silicon substrate 22 and accommodating buffer layer 24. Accommodating buffer layer 24 can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate 22 silicon lattice structure.

An accommodating buffer layer 24 formed of these zirconate or hafnate materials is suitable for the growth of compound semiconductor materials 26 in the indium phosphide (InP) system. The compound semiconductor material 26 can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template 30 for this structure is 110 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer 24, the surface is terminated with 1-2 monolayers of zirconium followed by deposition of 1-2 monolayers of arsenic to form a Zr—As template 30. A monocrystalline layer 26 of the compound semiconductor material from the indium phosphide system is then grown on template layer 30. The resulting lattice structure of the compound semiconductor material 26 exhibits a 45 degree rotation with respect to the accommodating buffer layer 24 lattice structure and a lattice mismatch to (100) InP of less than 2.5%, and preferably less than about 1.0%.

### EXAMPLE 3

In accordance with a further embodiment, a structure is provided that is suitable for the growth of an epitaxial film of a II-VI material overlying a silicon substrate 22. The substrate 22 is preferably a silicon wafer as described above. A suitable accommodating buffer layer 24 material is SrₓBa₁₋ₓTiO₃, where x ranges from 0 to 1, having a thickness of about 2-100 nm and preferably a thickness of about 5-15 nm. The II-VI compound semiconductor material 26 can be, for example, zinc selenide (ZnSe) or zinc sulfur selenide (ZnSSe). A suitable template 30 for this material system includes 110 monolayers of zinc-oxygen (Zn—O) followed by 1-2 monolayers of an excess of zinc followed by the selenidation of zinc on the surface. Alternatively, a template 30 can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, monocrystalline oxide layer 24, and monocrystalline compound semiconductor material layer 26 can be similar to those described in example 1. In addition, an additional buffer layer 32 serves to alleviate any strains that might result from a mismatch of the crystal lattice of the accommodating buffer layer and the lattice of the monocrystalline semiconductor material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying compound semiconductor material. The compositions of other materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline compound semiconductor material layer. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline compound semiconductor material layer 26 and template layer 30 can be the same as those described above in example 2. In addition, a buffer layer 32 is inserted between accommodating buffer layer 24 and overlying monocrystalline compound semiconductor material layer 26. Buffer layer 32, a further monocrystalline semiconductor material, can be, for example, a graded layer of indium gallium arsenide (InGaAs) or indium aluminum arsenide (InAlAs). In accordance with one aspect of this embodiment, buffer layer 32 includes InGaAs, in which the indium composition varies from 0 to about 47%. Buffer layer 32 preferably has a thickness of about 10-30 nm. Varying the composition of buffer layer 32 from GaAs to InGaAs serves to provide a lattice match between the underlying monocrystalline oxide material 24 and the overlying layer 26 of monocrystalline compound semiconductor material. Such a buffer layer 32 is especially advantageous if there is a lattice mismatch between accommodating buffer layer 24 and monocrystalline compound semiconductor material layer 26.

### EXAMPLE 6

This example provides exemplary materials useful in structure 34, as illustrated in FIG. 3. Substrate material 22, template layer 30, and monocrystalline compound semiconductor material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of semiconductor material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline compound semiconductor material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of accommodating buffer layer 24 and monocrystalline substrate 22 must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

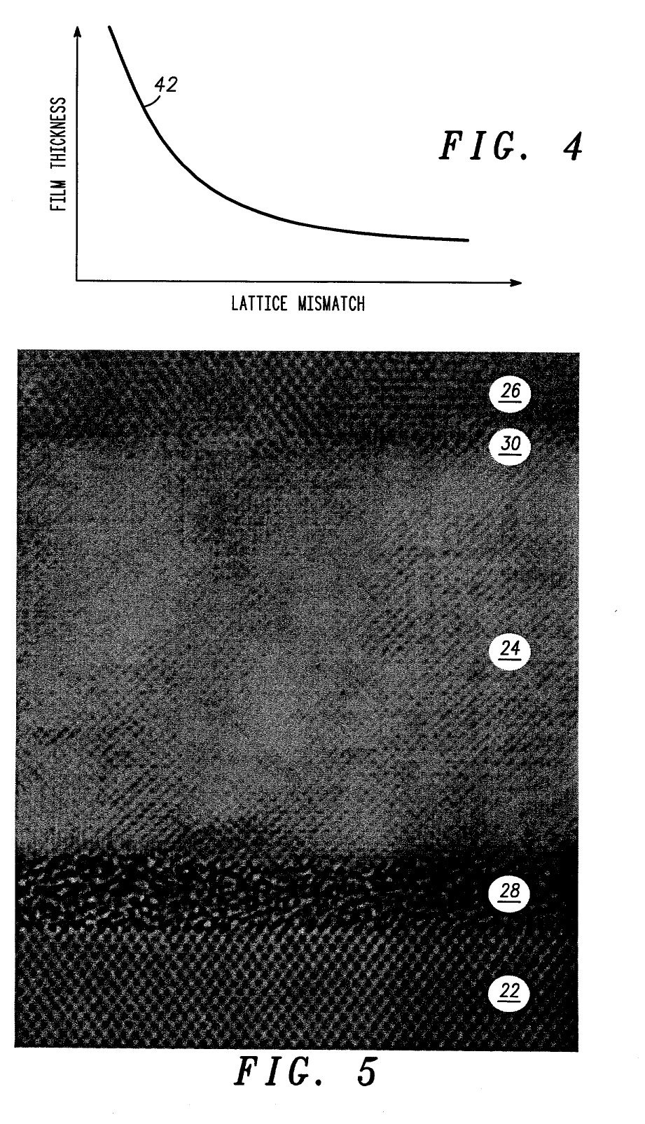

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that tend to be polycrystalline. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material 24 by 45° with respect to the crystal orientation of the silicon substrate wafer 22. The inclusion in the structure of amorphous interface layer 28, a silicon oxide layer in this example, if it is of sufficient thickness, serves to reduce strain in the titanate monocrystalline layer 24 that might result from any mismatch in the lattice constants of the host silicon wafer 22 and the grown titanate layer 24. As a result, a high quality, thick, monocrystalline titanate layer 24 is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, accommodating buffer layer 24 must be of high crystalline quality. In addition, in order to achieve high crystalline quality in layer 26, substantial matching between the crystal lattice constant of the host crystal, in this case, monocrystalline accommodating buffer layer 24, and grown crystal 26 is desired. With properly selected materials this substantial matching of lattice constants is achieved as a result of rotation of the crystal orientation of grown crystal 26 with respect to the orientation of host crystal 24. If grown crystal 26 is gallium arsenide, aluminum gallium arsenide, zinc selenide, or zinc sulfur selenide and accommodating buffer layer 24 is monocrystalline SrₓBa₁₋ₓTiO₃, substantial matching of crystal lattice constants of the two materials is achieved, wherein the crystal orientation of grown layer 26 is rotated by 45° with respect to the orientation of the host monocrystalline oxide 24. Similarly, if host material 24 is a strontium or barium zirconate or a strontium or barium hafnate or barium tin oxide and compound semiconductor layer 26 is indium phosphide or gallium indium arsenide or aluminum indium arsenide, substantial matching of crystal lattice constants can be achieved by rotating the orientation of grown crystal layer 26 by 45° with respect to host oxide crystal 24. In some instances, a crystalline semiconductor buffer layer 32 between host oxide 24 and grown compound semiconductor layer 26 can be used to reduce strain in grown monocrystalline compound semiconductor layer 26 that might result from small differences in lattice constants. Better crystalline quality in grown monocrystalline compound semiconductor layer 26 can thereby be achieved.

The following example illustrates a process, in accordance with one embodiment, for fabricating a semiconductor structure such as the structures depicted in FIGS. 1-3. The process starts by providing a monocrystalline semiconductor substrate 22 comprising silicon or germanium. In accordance with a preferred embodiment, semiconductor substrate 22 is a silicon wafer having a (100) orientation. Substrate 22 is preferably oriented on axis or, at most, about 0.50 off axis. At least a portion of semiconductor substrate 22 has a bare surface, although other portions of the substrate, as described below, may encompass other structures. The term “bare” in this context means that the surface in the portion of substrate 22 has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process. In order to epitaxially grow a monocrystalline oxide layer 24 overlying monocrystalline substrate 22, the native oxide layer must first be removed to expose the crystalline structure of underlying substrate 22. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate 22 is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer 24 of a monocrystalline oxide. The template provides the necessary chemical and physical properties to nucleate the crystalline growth of an overlying layer 24.

In accordance with an alternate embodiment, the native silicon oxide can be converted and the surface of substrate 22 can be prepared for the growth of a monocrystalline oxide layer 24 by depositing an alkali earth metal oxide, such as strontium oxide or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate 22 surface. Again, this forms a template for the subsequent growth of an ordered monocrystalline oxide layer 24.

Following the removal of the silicon oxide from the surface of substrate 22, the substrate is cooled to a temperature in the range of about 200-800° C. and a layer 24 of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer 28 at the interface between underlying substrate 22 and the growing strontium titanate layer 24. The growth of silicon oxide layer 28 results from the diffusion of oxygen through the growing strontium titanate layer 24 to the interface where the oxygen reacts with silicon at the surface of underlying substrate 22. The strontium titanate grows as an ordered monocrystal 24 with the crystalline orientation rotated by 45° with respect to the ordered 2×1 crystalline structure of underlying substrate 22. Strain that otherwise might exist in strontium titanate layer 24 because of the small mismatch in lattice constant between silicon substrate 22 and the growing crystal 24 is relieved in amorphous silicon oxide intermediate layer 28.

After strontium titanate layer 24 has been grown to the desired thickness, the monocrystalline strontium titanate is capped by a template layer 30 that is conducive to the subsequent growth of an epitaxial layer of a desired compound semiconductor material 26. For the subsequent growth of a layer 26 of gallium arsenide, the MBE growth of strontium titanate monocrystalline layer 24 can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template 30 for deposition and formation of a gallium arsenide monocrystalline layer 26. Following the formation of template 30, gallium is subsequently introduced to the reaction with the arsenic and gallium arsenide 26 forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with the present invention. Single crystal SrTiO3 accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

FIG. 6 illustrates an x-ray diffraction spectrum taken on a structure including GaAs compound semiconductor layer 26 grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer 32 deposition step. Buffer layer 32 is formed overlying template layer 30 before the deposition of monocrystalline compound semiconductor layer 26. If buffer layer 32 is a compound semiconductor superlattice, such a superlattice can be deposited, by MBE for example, on the template 30 described above. If instead buffer layer 32 is a layer of germanium, the process above is modified to cap strontium titanate monocrystalline layer 24 with a final layer of either strontium or titanium and then by depositing germanium to react with the strontium or titanium. The germanium buffer layer 32 can then be deposited directly on this template 30.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and semiconductor layer 38 to a rapid thermal anneal process with a peak temperature of about 700° C. to about 1000° C. and a process time of about 1 to about 10 minutes. However, other suitable anneal processes may be employed to convert the accommodating buffer layer to an amorphous layer in accordance with the present invention. For example, laser annealing or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution Transmission Electron Micrograph (TEM) of semiconductor material manufactured in accordance with the embodiment of the invention illustrated in FIG. 3. In accordance with this embodiment, a single crystal SrTiO3 accommodating buffer layer was grown epitaxially on silicon substrate 22. During this growth process, an amorphous interfacial layer forms as described above. Next, GaAs layer 38 is formed above the accommodating buffer layer and the accommodating buffer layer is exposed to an anneal process to form amorphous oxide layer 36.

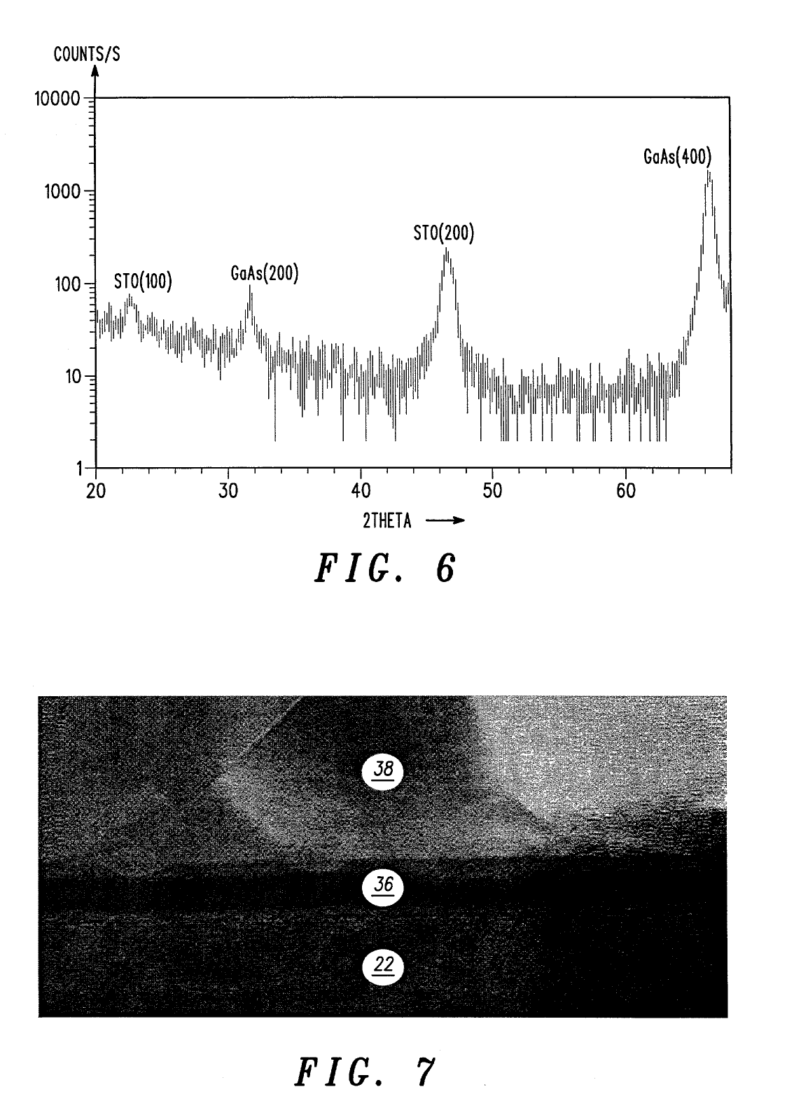

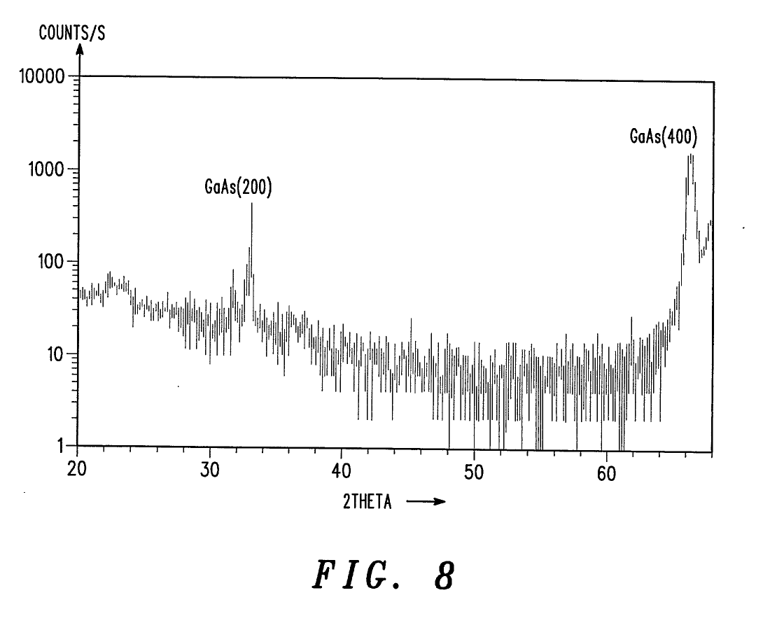

FIG. 8 illustrates an x-ray diffraction spectrum taken on a structure including GaAs compound semiconductor layer 38 and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate 22, an overlying oxide layer, and a monocrystalline gallium arsenide compound semiconductor layer 26 by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers 24 such as alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown. Further, by a similar process such as MBE, other III-V and II-VI monocrystalline compound semiconductor layers 26 can be deposited overlying monocrystalline oxide accommodating buffer layer 24.

Each of the variations of compound semiconductor materials 26 and monocrystalline oxide accommodating buffer layer 24 uses an appropriate template 30 for initiating the growth of the compound semiconductor layer. For example, if accommodating buffer layer 24 is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if monocrystalline oxide accommodating buffer layer 24 is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer 26, respectively. In a similar manner, strontium titanate 24 can be capped with a layer of strontium or strontium and oxygen, and barium titanate 24 can be capped with a layer of barium or barium and oxygen. Each of these depositions can be followed by the deposition of arsenic or phosphorus to react with the capping material to form a template 30 for the deposition of a compound semiconductor material layer 26 comprising indium gallium arsenide, indium aluminum arsenide, or indium phosphide.

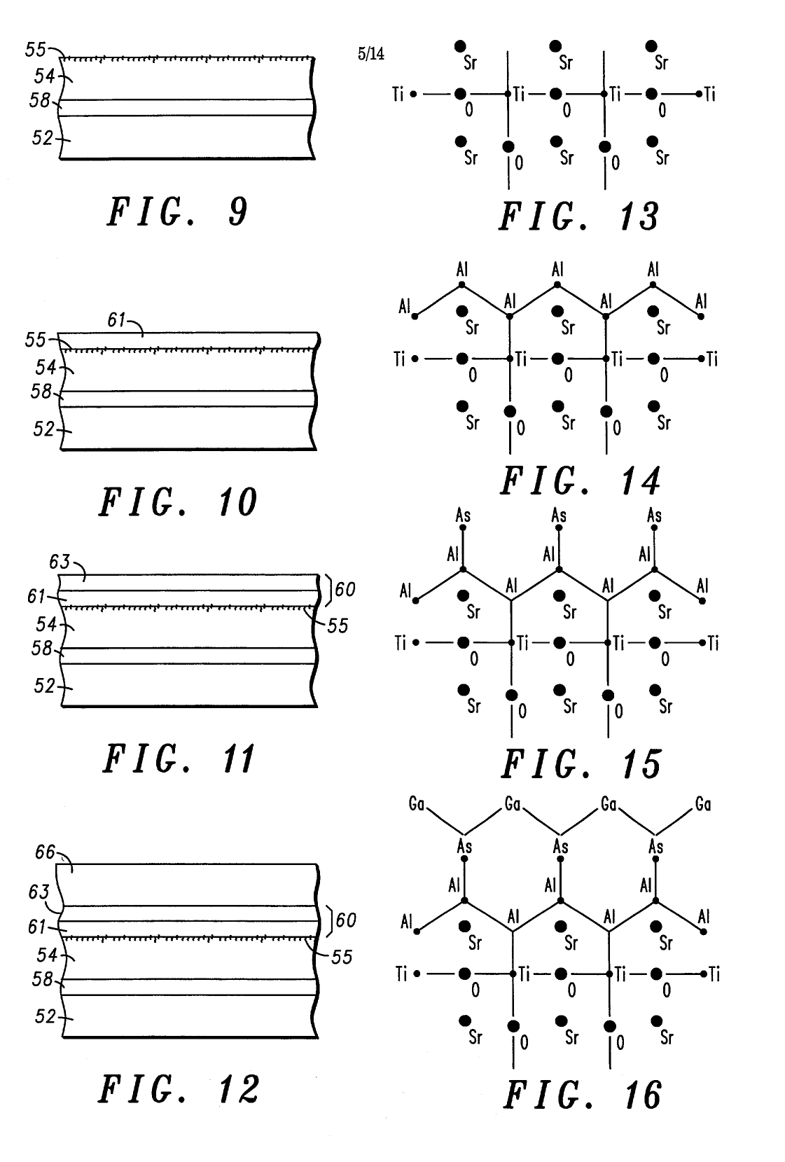

The formation of a device structure in accordance with another embodiment of the invention is illustrated schematically in cross-section in FIGS. 9-12. Like the previously described embodiments referred to in FIGS. 13, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference to layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, or the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 24 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 28 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

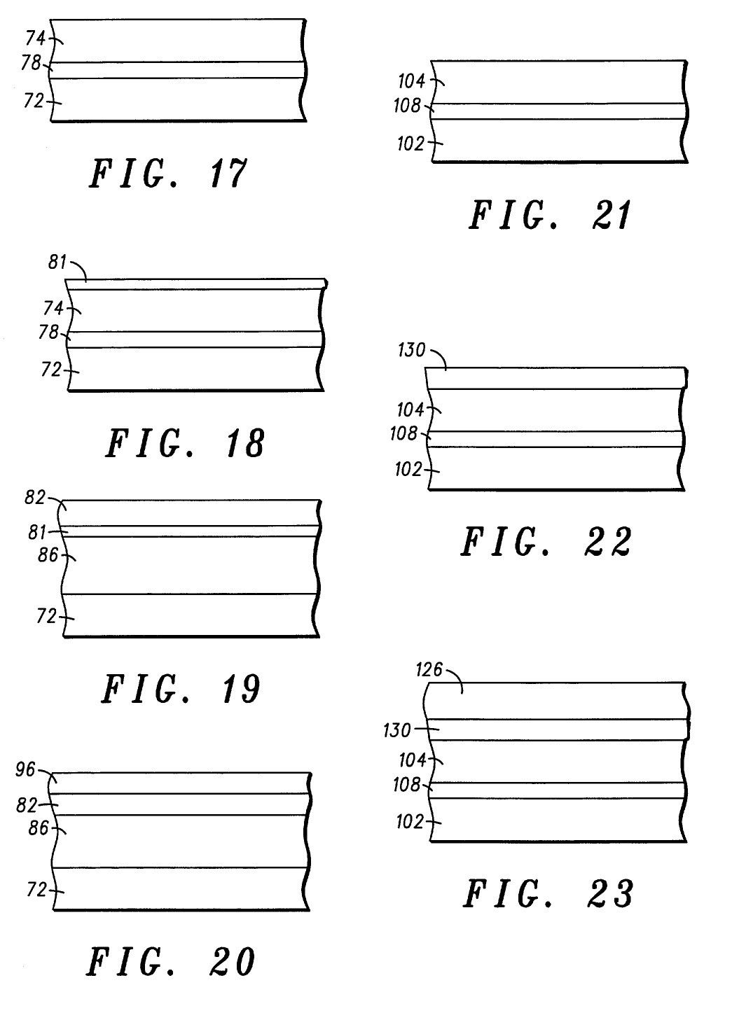

Finally, a compound semiconductor layer 96, shown in FIG. 20, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which adsorbs the strain between the layers. Moreover, unlike past use of a SiC substrate, this embodiment of the invention is not limited by wafer size which is usually less than 2 inches in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb) Ga₂, (Ca,Sr,Eu,Yb) In₂, BaGe₂As, and SrSn₂As₂.

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

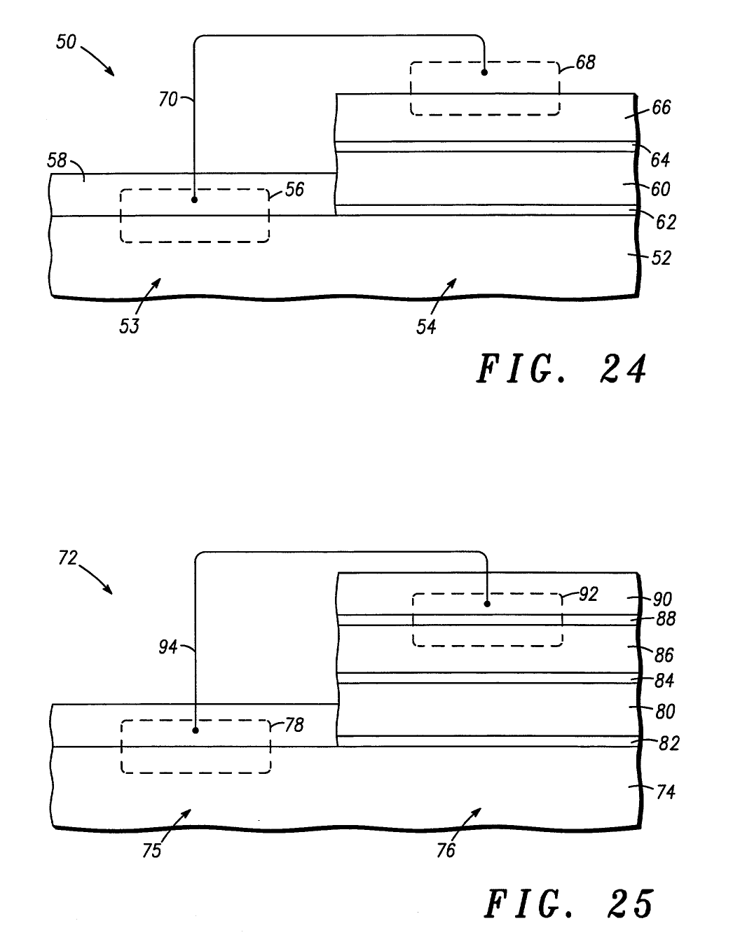

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 54. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 58 such as a layer of silicon dioxide or the like may overlie electrical semiconductor component 56.

Insulating material 58 and any other layers that may have been formed or deposited during the processing of semiconductor component 56 in region 53 are removed from the surface of region 54 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 54 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 54 to form an amorphous layer of silicon oxide 62 on second region 54 and at the interface between silicon substrate 52 and the monocrystalline oxide layer 60. Layers 60 and 62 may be subject to an annealing process as described above in connection with FIG. 3 to form a single amorphous accommodating layer.

In accordance with an embodiment, the step of depositing the monocrystalline oxide layer 60 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 60 and a gallium arsenide layer 66, similar devices can be fabricated using other substrates, monocrystalline oxide layers and other compound semiconductor layers as described elsewhere in this disclosure.

FIG. 25 illustrates a semiconductor structure 72 in accordance with a further embodiment. Structure 72 includes a monocrystalline semiconductor substrate 74 such as a monocrystalline silicon wafer that includes a region 75 and a region 76. An electrical component schematically illustrated by the dashed line 78 is formed in region 75 using conventional silicon device processing techniques commonly used in the semiconductor industry. Using process steps similar to those described above, a monocrystalline oxide layer 80 and an intermediate amorphous silicon oxide layer 82 are formed overlying region 76 of substrate 74. A template layer 84 and subsequently a monocrystalline semiconductor layer 86 are formed overlying monocrystalline oxide layer 80. In accordance with a further embodiment, an additional monocrystalline oxide layer 88 is formed overlying layer 86 by process steps similar to those used to form layer 80, and an additional monocrystalline semiconductor layer 90 is formed overlying monocrystalline oxide layer 88 by process steps similar to those used to form layer 86. In accordance with one embodiment, at least one of layers 86 and 90 are formed from a compound semiconductor material. Layers 80 and 82 may be subject to an annealing process as described above in connection with FIG. 3 to form a single amorphous accommodating layer.

A semiconductor component generally indicated by a dashed line 92 is formed at least partially in monocrystalline semiconductor layer 86. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 86 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 78 and component 92. Structure 72 thus integrates components that take advantage of the unique properties of the two monocrystalline semiconductor materials.

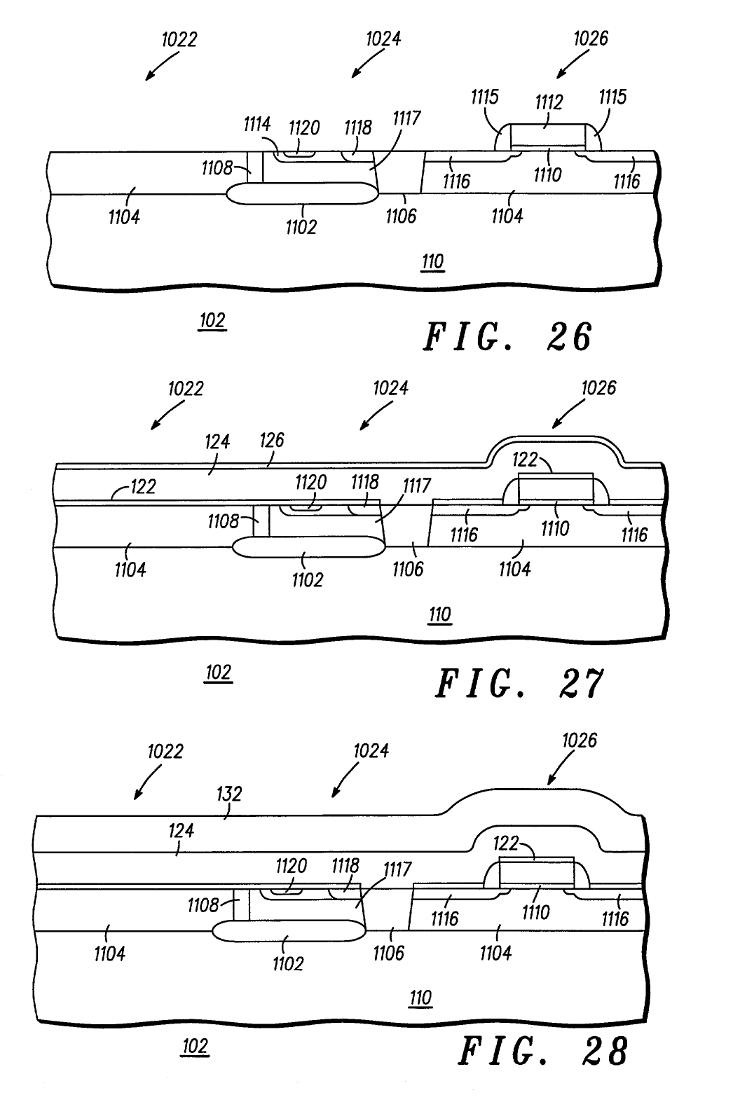

Attention is now directed to a method for forming exemplary portions of illustrative composite semiconductor structures or composite integrated circuits like 50 or 72. In particular, the illustrative composite semiconductor structure or integrated circuit 102 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. As of this point, no circuitry has been formed within the compound semiconductor portion 1022.

All of the layers that have been formed during the processing of the bipolar and MOS portions of the integrated circuit are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 102. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 126 is then formed and has a thickness in a range of approximately one to ten monolayers of a material. In one particular embodiment, the material includes titanium-arsenic, strontium-oxygen-arsenic, or other similar materials as previously described with respect to FIGS. 1-5. Layers 122 and 124 may be subject to an annealing process as described above in connection with FIG. 3 to form a single amorphous accommodating layer.

A monocrystalline compound semiconductor layer 132 is then epitaxially grown overlying the monocrystalline portion of accommodating buffer layer 124 (or over the amorphous accommodating layer if the annealing process described above has been carried out) as shown in FIG. 28. The portion of layer 132 that is grown over portions of layer 124 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-500 nm. In this particular embodiment, each of the elements within the template layer are also present in the accommodating buffer layer 124, the monocrystalline compound semiconductor material 132, or both. Therefore, the delineation between the template layer 126 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

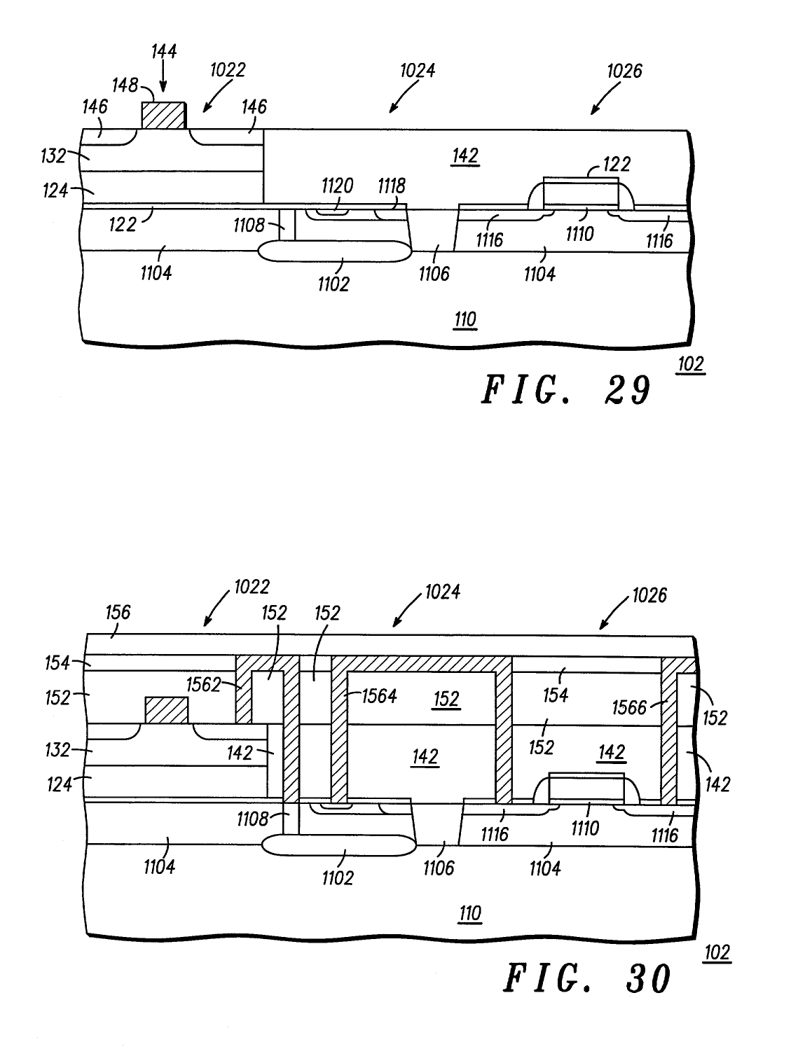

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section is removed, an insulating layer 142 is then formed over the substrate 110. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished, removing portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and monocrystalline compound semiconductor layer 132 are also n-type doped. If a p-type MESFET were to be formed, then the doped regions 146 and monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 102 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown.

A passivation layer 156 is formed over the interconnects 1562, 1564, and 1566 and insulating layer 154. Other electrical connections are made to the transistors as illustrated as well as to other electrical or electronic components within the integrated circuit 102 but are not illustrated in the FIGs. Further, additional insulating layers and interconnects may be formed as necessary to form the proper interconnections between the various components within the integrated circuit 102.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion into the compound semiconductor portion 1022 or the MOS portion 1024. Therefore, the requirement of special fabricating steps solely used for making a bipolar transistor can be eliminated. Therefore, there would only be a compound semiconductor portion and a MOS portion to the integrated circuit.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections to the external electronic circuitry. The composite integrated circuit may also have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communications synchronization information.

For clarity and brevity, optical detector components that are discussed herein are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

In accordance with the principles of the present invention, the process heretofore described can be carried out in reverse, as shown in FIGS. 31-36, to provide a semiconductor structure or integrated circuit having both (a) one or more compound semiconductor portions and (b) at least one non-compound semiconductor portion such as a monocrystalline silicon portion, as in FIGS. 26-30, but with the compound semiconductor portion as the substrate. In FIG. 31, the non-compound semiconductor portions resemble “mesas” sitting atop the surface of the compound semiconductor substrate. In FIGS. 32-36, the non-compound semiconductor portions are flush with the surface of a compound semiconductor substrate. Although the discussion of these embodiments, which may be referred to as embodiments of a “hybrid” semiconductor, will focus for convenience on silicon as the non-compound semiconductor portion, it will be understood that any non-compound semiconductor portion, such as a different Group IV semiconductor portion, may also be used.

With reference now to FIG. 31, hybrid semiconductor device 1150 is similar to hybrid semiconductor device 50 of FIG. 24, except that where semiconductor device 50 includes a non-compound semiconductor with a conventional non-compound semiconductor region 53 and a compound semiconductor “mesa” formed on region 54, hybrid semiconductor device 1150 has a compound semiconductor region 1153 and a non-compound semiconductor “mesa” formed on region 1154.

Thus, device structure 1150 includes a monocrystalline compound semiconductor substrate 1152, preferably a monocrystalline GaAs wafer. The process described above preferably is carried out in reverse to form, preferably, template layer 1162 and accommodating buffer layer 1160, respectively similar to template layer 30 and accommodating buffer layer 24 described above. Monocrystalline non-compound semiconductor layer 1166 of, e.g., silicon, is then grown on accommodating buffer layer 1160, after which entry of oxygen into accommodating buffer layer 1160 results in the formation of amorphous layer 1164, similar to amorphous layer 28 described above. As above, amorphous layer 1164 and accommodating buffer layer 1160 may be annealed to form a single amorphous accommodating layer.

Preferably, amorphous layer 1164, accommodating buffer layer 1160, and template layer 1162, or as many layers as are present (one or more may be omitted or may be annealed to form a single layer)—which may be referred to collectively as insulating layer 1161, insulate the non-compound semiconductor layer 1166 from compound semiconductor substrate 1152. One of the layers in insulating layer 1161 or a combination of the layers in insulating layer 1161 may comprise electrical insulation that is sufficient to make insulating layer 1161 an insulator. For example, insulator layer 1161 may comprise a layer of strontium titanate for accommodating buffer layer 1160 to provide electrical insulation, an insulator, between non-compound semiconductor layer 1166 and compound semiconductor substrate 1152.

Next, the layers deposited on monocrystalline compound semiconductor substrate 1152 preferably are removed in region 1153, leaving a “mesa” of monocrystalline non-compound semiconductor material in region 1154. A CMOS or other component 1156 may be formed in layer 1166 either before or after removal of material to form the “mesa.” An electrical semiconductor component generally indicated by the dashed line 1168 may then be formed in region 1153 of substrate 1152. Semiconductor component 1168 can then be formed by processing steps conventionally used in the fabrication of gallium arsenide or other III-V compound semiconductor material devices. Insulating material 1158 and any other layers that may be necessary can be formed or deposited during the processing of semiconductor component 1168 in region 1153. Semiconductor component 1168 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. Components 1156 and 1168 may be connected by metallization 1170.

Other hybrid semiconductor structures may also be formed and used. For example, with reference now to FIG. 32, hybrid semiconductor 200 includes a monocrystalline compound semiconductor (e.g., GaAs) substrate 201 in which depressions or wells 202 have been formed. Each well 202 is filled with a non-compound (e.g., silicon) semiconductor portion, which may be thought of as an “island” 204 of non-compound semiconductor in the compound semiconductor, as seen in the plan view of FIG. 33.

Hybrid semiconductor 200 may be made by forming wells 202 in the compound—e.g., monocrystalline GaAs—semiconductor substrate 201. Wells 202 may be formed, e.g., by any well-known etching process including both wet and dry etching processes, operating on the compound semiconductor material. While wells 202 may be substantially circular or of other shapes, they preferably are substantially rectangular as shown, with dimensions on the order of hundreds of micrometers on a side, providing an area sufficient to form a useful amount of circuitry.

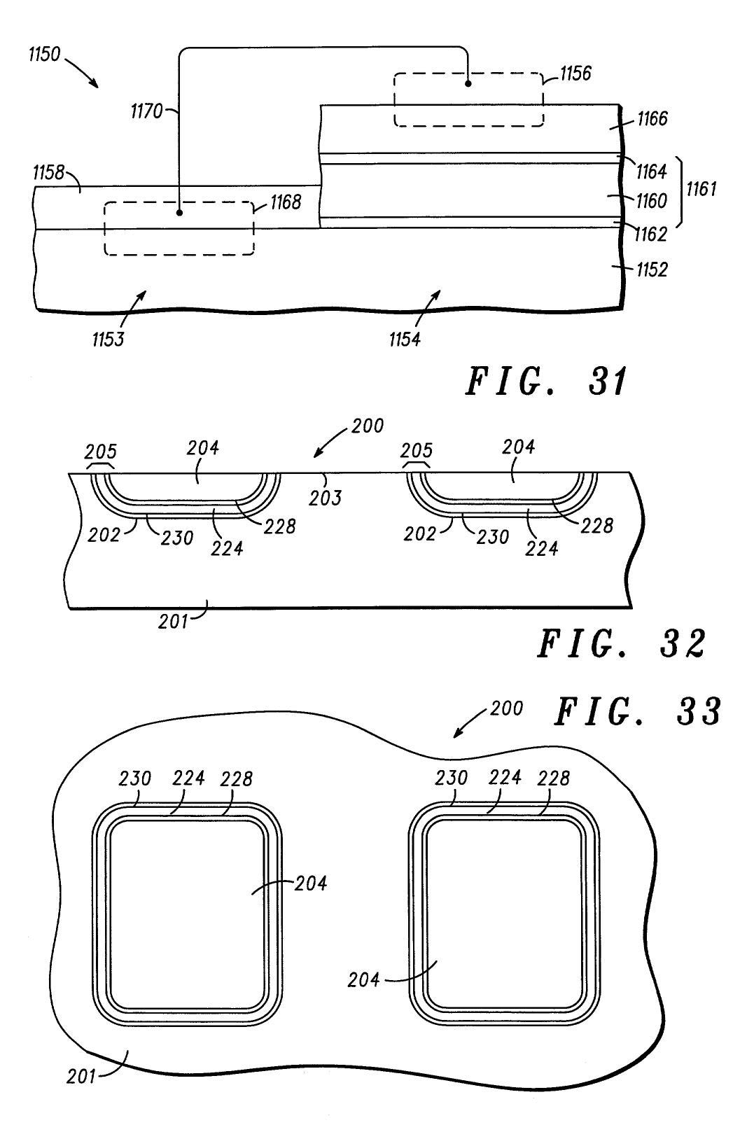

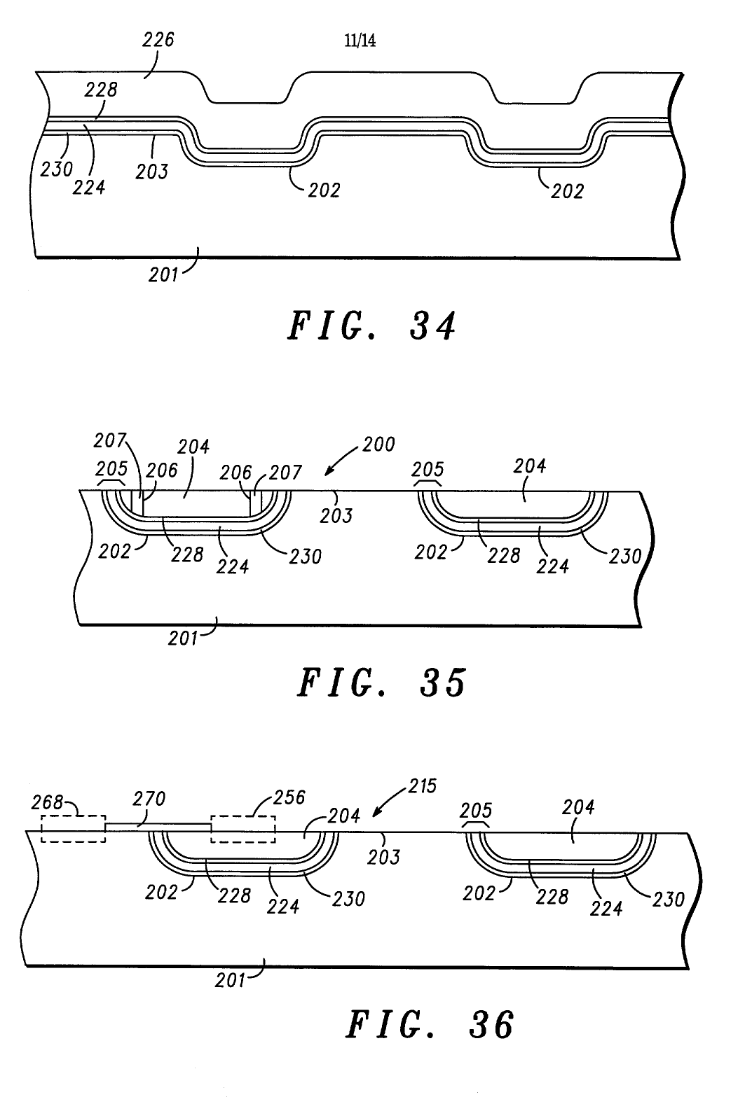

After wells 202 have been formed in monocrystalline compound semiconductor substrate 201, the process described above is carried out in reverse to form, preferably, template layer 230 and accommodating buffer layer 224, respectively similar to template layer 30 and accommodating buffer layer 24 described above (see FIG. 1). Monocrystalline non-compound semiconductor layer 226 of, e.g., silicon, is then grown on accommodating buffer layer 224, after which entry of oxygen into accommodating buffer layer 224 results in the formation of amorphous layer 228, similar to amorphous layer 28 described above. The final result is a structure such as that shown in cross section in FIG. 34. As above, amorphous layer 228 and accommodating buffer layer 224 may be annealed to form a single amorphous accommodating layer. Monocrystalline non-compound semiconductor layer 226 substantially follows the contours of monocrystalline compound semiconductor substrate 201, including the contours of wells 202.

A polishing step, which can be any conventional semiconductor polishing technique such as chemical/mechanical polishing (CMP), is then used to remove monocrystalline non-compound semiconductor layer 226, amorphous layer 228, accommodating buffer layer 224, and template layer 230, down to the original surface 203 of substrate 201. The result is the hybrid structure 200 shown in FIGS. 32 and 33, in which islands 204 of silicon (or other monocrystalline non-compound semiconductor) are present in the surface of the compound semiconductor substrate 201. Preferably, amorphous layer 228, accommodating buffer layer 224, and template layer 230, or as many of those layers as are present (one or more may be omitted, or layers 224 and 228 may be annealed to form a single layer as above)—which may be referred to collectively as insulating layer 205, insulate the non-compound semiconductor islands 204 from the compound semiconductor 201.

One of the layers in insulating layer 205 or a combination of the layers in insulating layer 205 may comprise electrical insulation that is sufficient to make insulating layer 205 an insulator. For example, insulator layer 205 may comprise a layer of strontium titanate for accommodating buffer layer 224 to provide, among other things, electrical insulation, an insulator, between compound semiconductor substrate 201 and islands 204.

If insulating layer 205 does not grow sufficiently on the side walls of wells 202 to provide adequate insulation at the edges of island 204, then as shown in FIG. 35 a trench 206 may be cut around the periphery of island 204, using conventional semiconductor trench-forming techniques, and filled with a suitable insulating material 207, which may be, e.g., a silicon oxide, or one of the components of insulating layer 205.

The depth of each well 202, and thus the thickness of each island 204 (the thicknesses of the amorphous layer 228, accommodating buffer layer 224, and template layer 230 total between about 10 Å and about 100 Å and are therefore negligible), preferably is between about 0.5 μm and about 2 μm.

Once hybrid structure 200 has been formed, electronic circuitry can be created by forming electronic components 268 and 256 (FIG. 36) in substrate 201 and island 204, respectively. The components can be interconnected by appropriate metallization 270 as shown in FIG. 36, resulting in hybrid integrated circuit device 215.

Component processing in materials such as monocrystalline silicon is typically carried out at temperatures above about 800° C., while component processing in compound semiconductor materials such as GaAs is typically carried out at lower temperatures, between about 300° C. and about 800° C., and components formed in GaAs would be damaged by the higher temperatures of silicon processing (although the unprocessed GaAs itself would not be damaged). Therefore, preferably components such as component 1156 or 256 are formed first in silicon layer 1166 or silicon island 204 using high-temperature processing. Components such as component 1168 or 268 are then formed in the GaAs substrate 1152 or 201 at the lower processing temperatures, which will not damage the already formed silicon components 1156 or 256.

Hybrid semiconductor structures, such as the hybrid semiconductor structures of FIGS. 31-49 may provide cost effective techniques and structures for implementing field effect transistors with back gates for use in high density integrated circuits. In some applications, a back gate for a device may be desired for VLSI circuitry that is implemented in hybrid semiconductor structures, such as, a VLSI field effect transistor. Back gates may be provided without substantially increasing production costs and without substantially decreasing device density.

For clarity and brevity, back gates are discussed primarily in the context of back gates that are for field effect transistors. The techniques and structures discussed herein may also be applied by those skilled in the art in building suitable back gates for other semiconductor devices.

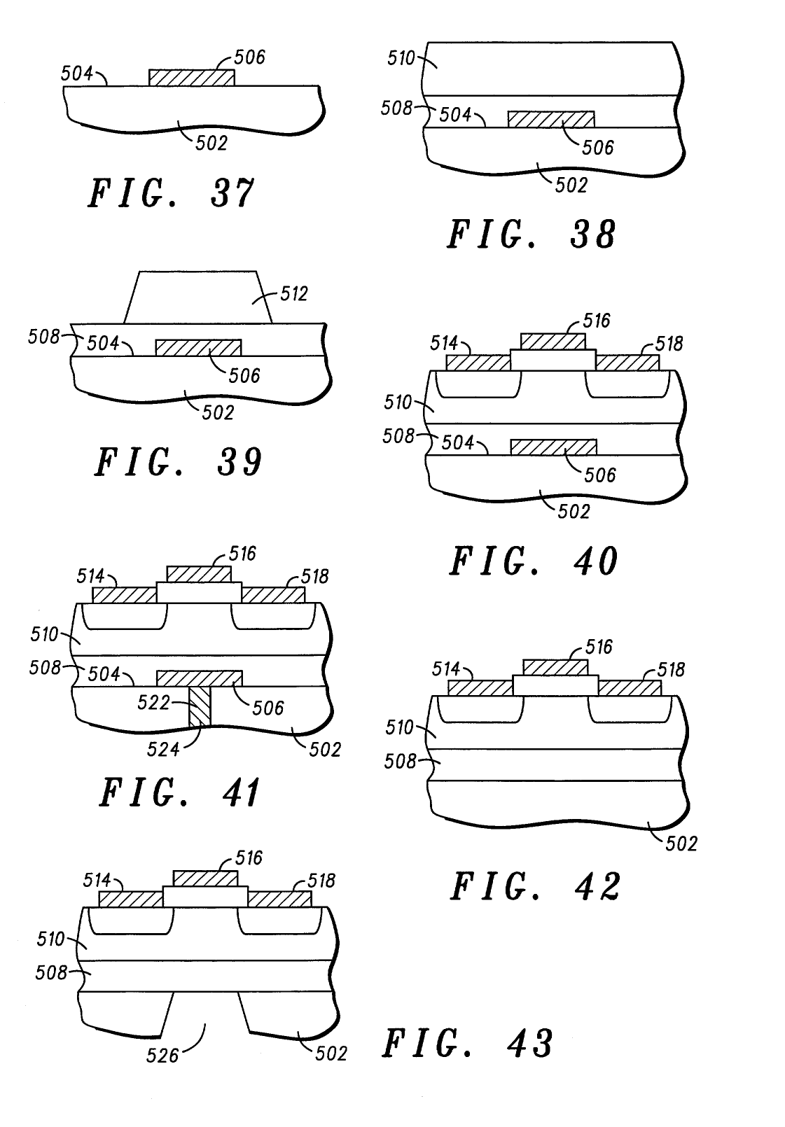

In a first illustrated back gate embodiment, a contact for a back gate of a field effect transistor may be formed after a field effect transistor is formed in a hybrid semiconductor structure. For example, with reference now to FIGS. 37-41, compound semiconductor region 502 may comprise compound semiconductor materials and may be part of a compound semiconductor substrate. However, if desired, compound semiconductor region 502 may be part of a compound semiconductor layer that is formed over a non-compound semiconductor substrate, such as, compound semiconductor layer 142 that is formed over substrate 110 shown in FIG. 29. For clarity and brevity, compound semiconductor region 502 is primarily discussed in the context of a region that comprises GaAs and primarily referred to as GaAs region 502. Surface 504 of GaAs region 502 may have been formed using conventional processing techniques (e.g., using a polishing step).

On surface 504 of GaAs region 502, contact 506 may be formed. Contact 506 may be a conductor formed on GaAs region 502 to form part of the back gate of a field effect transistor. Contact 506 may be a metal semiconductor that is formed on GaAs region 502 through epitaxial growth of a metal semiconductor. Contact 506 may comprise sufficient amounts of metal to be a conductor.

With reference now to FIG. 38, insulating layer 508 may be formed over GaAs region 502. Insulating layer 508 may be formed using techniques such as the techniques that are discussed above for forming insulating layer 1161 of FIG. 31 and insulating layer 205 of FIG. 32. Insulating layer 508 may include an amorphous layer, an accommodating buffer layer, and a template layer, or as many of those layers as are present (one or more may be omitted, or accommodating buffer layer 224 and amorphous layer 228 may be annealed, using techniques discussed above, to form a single layer as above).

Non-compound semiconductor region 510 may be formed over insulating region 508 based on the techniques that are discussed above (e.g., in connection with FIG. 31) for forming composite compound semiconductor and non-compound semiconductor structures. Non-compound semiconductor region 510 may comprise monocrystalline Group IV semiconductor materials, such as silicon. For clarity and brevity, non-compound semiconductor region 510 is primarily referred to as Si region 510.

Insulating layer 508 may comprise electrical insulation that is provided by one or more layers that are present therein, such as an accommodating buffer layer, a template layer, and an amorphous layer. Insulating layer 508 may have sufficient electrical insulation to act as an insulator. For example, insulating layer 508 may comprise an accommodating buffer layer of strontium titanate that, among other things, acts as an insulator between GaAs region 502 and Si region 510.

GaAs region 502 may be a compound semiconductor region in a compound semiconductor substrate that is on one side of a composite semiconductor wafer. On an opposing side of the composite semiconductor wafer, there may be a non-compound semiconductor substrate that may include a non-compound semiconductor region, such as, Si Region 510. Insulating layer 508 may be included in the wafer in between the two opposing sides of compound and non-compound semiconductor materials.

If desired, the structure of the wafer may be formed differently. For example, non-compound semiconductor islands (e.g., see FIGS. 32 and 33) may be formed in a compound semiconductor substrate of a wafer with an insulating layer separating the islands and the compound semiconductor substrate.

As shown in FIG. 39, if desired before further processing Si region 510, mesa 512 may be formed by etching Si region 510. Insulating layer 508 may be used to provide vertical isolation between opposing compound and non-compound semiconductor regions (e.g., GaAs region 502 and Si region 510) and between semiconductor devices that may have been formed in those opposing regions.

With reference now to FIG. 40, a non-compound semiconductor field effect transistor (e.g., a MOSFET) having source 514, drain 518, and gate 516 may be formed by applying conventional processing techniques on Si region 510 of FIG. 38. Source 514, drain 518, and gate 516 may each include contacts that have been formed over appropriate source, drain, and gate regions in Si region 510. Gate 516 may be an insulated gate, which has a contact that is insulated from the body of the field effect transistor.

Contact 506 may be part of a back gate for a field effect transistor that also comprises source 514, gate 516, and drain 518. With reference now to FIG. 41, via 522 may be formed in Si region 502 and filled with connecting conductor 524 to provide a path for forming an electrical connection with contact 506. Connecting conductor 524 may be formed in via 522 using techniques that are illustratively shown above or using techniques known to those skilled in the art. Contact 506 may be positioned to partly overly GaAs region 506 and partly overlie connecting conductor 522. One advantage of this technique for forming a field effect transistor is that contact 506 that is in between Si region 510 and GaAs region 502 may be used as a selective etch-stop for forming via 522. The use of a selective etch-stop may simplify the process and may make the processing of back gates for field effect transistors less expensive. Other advantages may involve the diverse functionality that is available when compound and non-compound semiconductor devices are integrated in a single semiconductor structure.

Insulation layer 508 may provide sufficient insulation to insulate contact 506 from the body of the non-compound semiconductor field effect transistor. Insulated contact 508 may be part of the back gate of the field effect transistor. Contact 506 may be used to conduct electricity through capacitive action between contact 506 and the body of the field effect transistor. Insulating layer 508 may also be used to provide electrical isolation between devices in the opposing regions. Lateral insulation for the field effect transistor may be provided for example, by forming trenches of insulating materials on the sides of the field effect transistor. Insulation trenches on the sides of the field effect transistor may be formed by using insulation layer 508 as a selective etch-stop. Insulation layer 508 may comprise strontium titanate.

If desired, a back gate may be formed after, rather than before, forming source or drain parts of a field effect transistor. For example, with reference now to FIG. 42, source 514, drain 518, and gate 516 may be formed by applying techniques that are illustratively shown above or techniques known to those skilled in the art to Si region 510 overlying GaAs region 502.

In the structures illustratively shown in FIGS. 42-44, Si region 510 may be a non-compound semiconductor region that comprises silicon or comprises some other non-compound semiconductor that for clarity and brevity is referred to herein as Si region 510. GaAs region 502 may be a compound semiconductor region that comprises Gallium Arsenide or some other compound semiconductor material that for clarity and brevity is referred to herein as GaAs region 502. The two regions, Si region 510 and GaAs region 502, may be on opposing sides of insulating layer 508. Insulating layer 508 may substantially relieve structural strains between Si region 510 and GaAs region 502 and may also provide vertical electrical isolation between Si region 510 and GaAs region 502.

With reference now to FIG. 43, insulating layer 508, which may comprise strontium titanate, may be used as an etch-stop in a selective etch to form trench 526 in GaAs region 502. With reference now to FIG. 44, contact 528 may be deposited on insulating layer 508 in trench 526. Connection circuitry may be provided for contact 528 by forming (e.g., by depositing) connecting conductor 530 that extends from contact 528 to an area outside of the trench.

One advantage of such techniques and structures may be that an insulating layer between two different types of semiconductor materials may provide both vertical insulation between devices in those regions and insulation for insulated back gates in those regions.

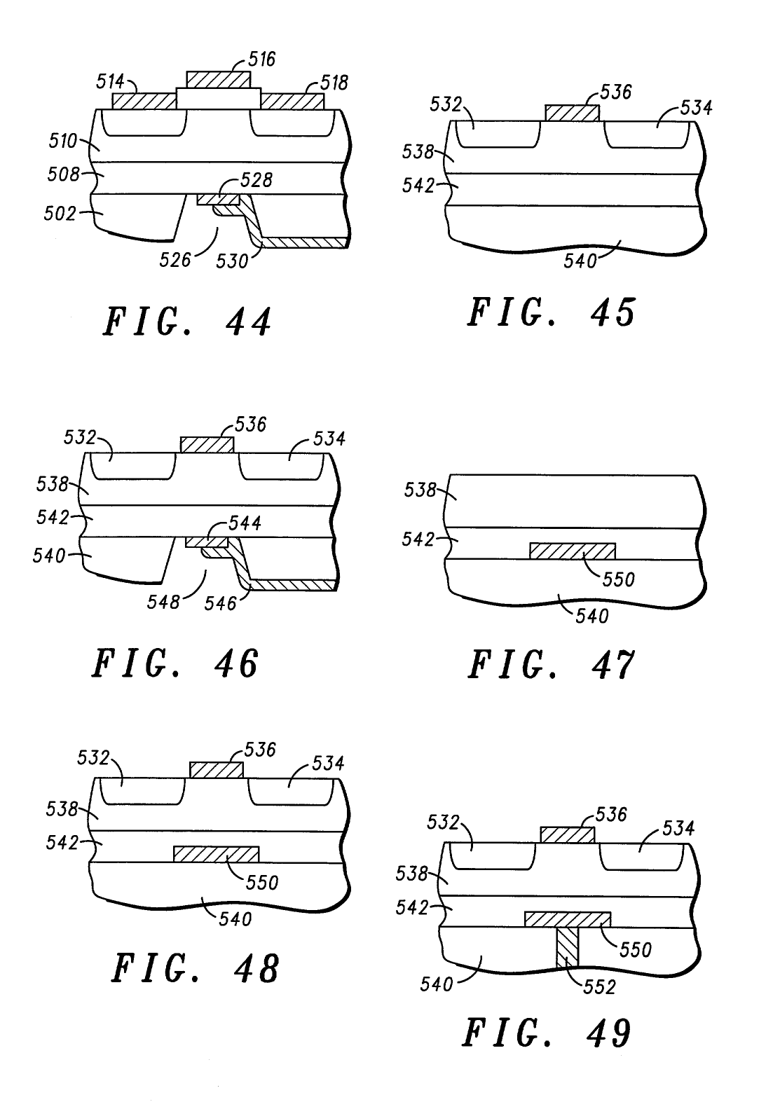

A hybrid semiconductor structure may also be used to form a compound semiconductor field effect transistor that has a back gate. With reference now to FIG. 45, compound semiconductor region 538 may be on one side of insulating layer 542 that opposes non-compound semiconductor region 540. Source 532, drain 539, and gate 536 may be formed by applying techniques illustratively shown above or techniques known to those skilled in the art to compound semiconductor region 538. Source 532, drain 539, and gate 536 may be formed when forming a field effect transistor. Gate 536 may include a contact that is formed over the body of the field effect transistor. Contact 544 that is for a back gate may be deposited in trench 548 over insulating layer 592 that insulates the opposing compound semiconductor region 538 and non-compound semiconductor region 540. Connecting conductor 546 may be deposited to allow for an electrical connection with contact 544.

If desired, a contact for a back gate of a compound semiconductor field effect transistor may be formed before forming a source or drain. With reference now to FIG. 47, contact 550 may be formed over non-compound semiconductor region 540 (e.g., formed using epitaxial growth of metal semiconductor material) before forming insulating layer 542 and compound semiconductor region 538. With reference now to FIG. 48, source 532, drain 534, and gate 536 may be formed using compound semiconductor region 538 to provide a compound semiconductor field effect transistor. With reference now to FIG. 49, a selective etch-stop may be used to form a via that reaches contact 550. A connection for electrical signals for contact 550 may be provided by depositing connection conductor 552 in the via.

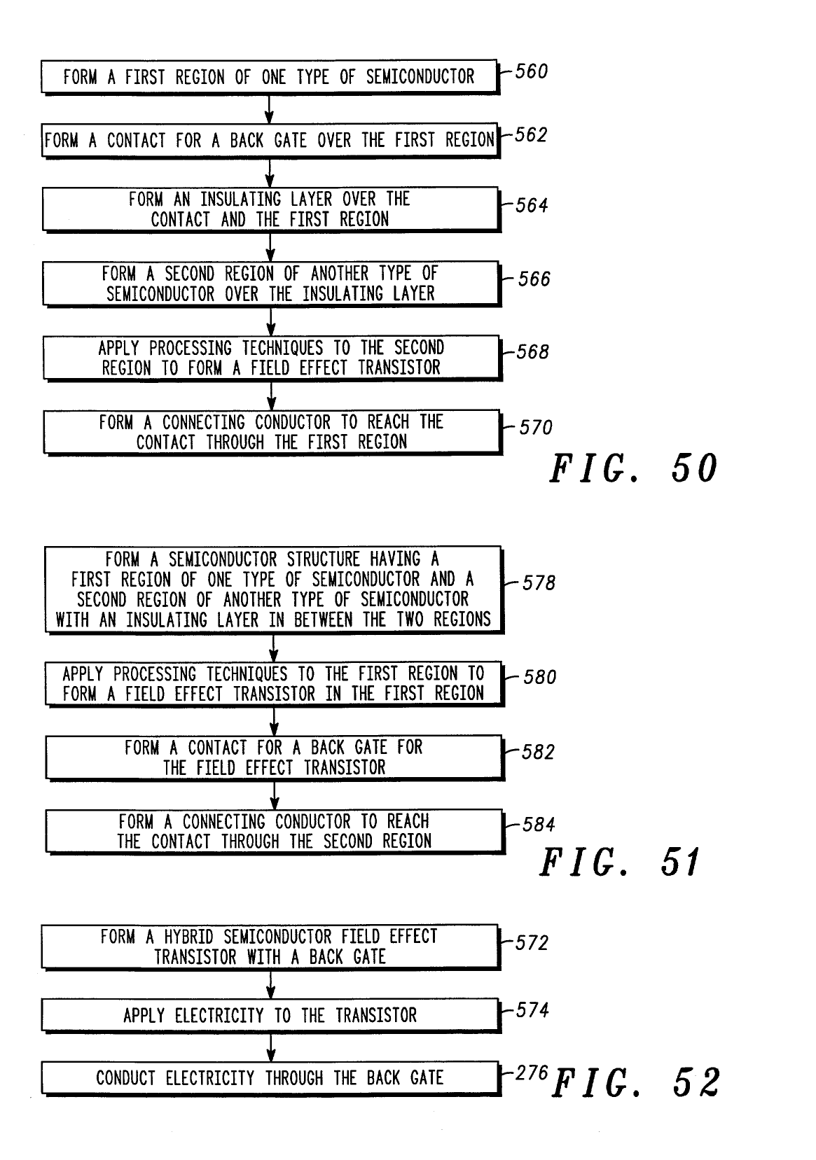

Illustrative steps involved in forming a device such as a field effect transistor with a back gate are shown in FIG. 50. At step 560, a first region of one of type of semiconductor may be formed. For example, a compound semiconductor region may be formed using the techniques described herein or using techniques known to those skilled in the art. At step 562, a contact for a back gate may be formed over the first region (e.g., may be formed by growing a metal semiconductor over a portion of the first region). At step 564, an insulating layer may be formed over the contact and the first region (e.g., form an accommodating buffer layer that also serves as an insulator). At step 566, a second region of another type of semiconductor may formed over the insulating layer. For example, a non-compound semiconductor region may be formed over an insulating layer that overlies a compound semiconductor region. At step 568, processing techniques may be applied to the second region to form a field effect transistor (e.g., a non-compound field effect transistor may be formed to operate in the second region when the second region is a non-compound semiconductor region). The field effect transistor may have a transistor body that overlies the contact. The contact may include metal or a mixture of metal and other materials. At step 570, a connecting conductor may be formed that reaches the contact through the first region (e.g., the connecting conductor reaches the contact through a compound semiconductor region when the second region is a compound semiconductor region). The structures that are illustratively shown in FIGS. 37-41 and in FIGS. 47-49 may be provided based on the illustrative steps of FIG. 50.

As discussed above, a back gate for a device such as a field effect transistor may be formed after forming parts of the field effect transistor. For example, illustrative steps involved in forming a back gate of a field effect transistor after forming the field effect transistor are shown in FIG. 51. At step 578, a semiconductor structure may be formed that includes a first region of one type of semiconductor and a second region of another type of semiconductor that have an insulating layer in between (e.g., a non-compound semiconductor region may be formed overlying an insulating layer that overlies a compound semiconductor region, etc.). Examples of techniques for forming such structures are illustratively discussed herein. At step 580, processing techniques may be applied to form a field effect transistor in the first region (e.g., form a non-compound semiconductor field effect transistor). At step 582, a contact may formed for a back gate for the field effect transistor. For example, the insulating layer may be used as an etch stop to form a via through the second region and a contact may be deposited on the insulating layer opposite the body of the field effect transistor. At step 584, a connecting conductor may be formed to reach the contact through the second region. The structures that are illustratively shown in FIGS. 42-44 and in FIGS. 45 and 46 may be provided based on the illustrative steps of FIG. 51.

A field effect transistor with a back gate may be a field effect transistor that includes components that may be used to apply electricity to or conduct electricity through one side of a field effect transistor away from the source, drain, and gate of the transistor. For example as shown in FIGS. 37-49, contacts 506, 528, 544, and 580 may each be used to apply electricity to the body of the field effect transistor from a side that opposes the source, drain, and the gate (i.e., the bulk side) of the illustrated field effect transistors. The operation and uses of field effect transistors with back gates are known to those skilled in the art.

With reference now to FIG. 52, after forming a hybrid semiconductor field effect transistor with a back gate at step 572, electricity may be applied to the field effect transistor at step 574. At step 576, an electrical current may pass through the back gate in response to the electricity applied the transistor at step 574. In most applications, current flow through the back gate occurs through capacitive action between the back gate and the body of the field effect transistor.

In forming a non-compound semiconductor device with a back gate that overlies a compound semiconductor region (e.g., FIGS. 37-44), the compound semiconductor region may be a compound semiconductor wafer (e.g., a GaAs wafer) or a compound semiconductor layer that is formed over a non-compound semiconductor (e.g., a Group IV monocrystalline semiconductor wafer). Also, the non-compound semiconductor device may be formed by applying processing techniques to a non-compound semiconductor mesa or well (e.g. wells shown in FIGS. 32).

In forming a compound semiconductor device with a back gate that overlies a non-compound semiconductor region (e.g., FIGS. 45-49), the non-compound semiconductor region may be a non-compound semiconductor wafer (e.g., a Group IV monocrystalline semiconductor wafer) or a non-compound semiconductor layer that is formed over a compound semiconductor (e.g., a GaAs water). Also, the compound semiconductor device may be formed by applying processing techniques to a compound semiconductor mesa or well.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The invention claimed is:

1. A hybrid semiconductor structure comprising:
a compound semiconductor region;
an insulating layer that overlies the compound semiconductor region;
a non-compound semiconductor field effect transistor having a body that overlies the insulating layer that overlies the compound semiconductor region;
an insulated back gate for the field effect transistor that is insulated from the body of the field effect transistor by the insulating layer and that includes a connecting conductor that reaches the back gate through the compound semiconductor region.

2. The device of claim 1, wherein the back gate comprises a contact that is positioned partly over the compound semiconductor region.

3. The device of claim 2, wherein the connecting conductor reaches the contact through a via in the compound semiconductor region.

4. The device of claim 3, wherein the back gate comprises a contact that is insulated from the body of the field effect transistor with the insulating layer.

5. The device of claim 4, wherein the connecting conductor reaches the contact through a trench that extends to the insulating layer.

6. The device of claim 1, wherein the field effect transistor is configured to have the back gate conduct electricity through capacitive action with the body of the field effect transistor.

7. The device of claim 6, wherein the back gate comprises a contact that is positioned partly over the compound semiconductor region.

8. The device of claim 7, wherein the connecting conductor reaches the contact through a via in the compound semiconductor region.

9. The device of claim 8, wherein the back gate comprises a contact that is insulated from the body of the field effect transistor with the insulating layer.

10. The device of claim 9, wherein the connecting conductor reaches the contact through a trench that extends to the insulating layer.

11. A method comprising:
forming a compound semiconductor region;
forming an insulating layer that overlies the compound semiconductor region;
forming a non-compound semiconductor region overlying the insulating layer; and
forming in the non-compound semiconductor region a non-compound semiconductor field effect transistor having a body that overlies the insulating layer and a back gate that is insulated from the body of the field effect transistor by the insulating layer.

12. The method of claim 11, wherein forming the back gate comprises forming a contact that is insulated from the body of the field effect transistor by the insulating layer.

13. The method of claim 12, wherein forming the contact is performed before forming a source and a drain for the field effect transistor.

14. The method of claim 12, wherein forming the contact is performed after forming a source and a drain for the field effect transistor.

15. The method of claim 12, wherein forming the contact comprises etching through the compound semiconductor region to reach the insulating layer.

16. The method of claim 12, wherein forming the contact comprises epitaxially growing the contact over the compound semiconductor region before forming the insulating layer.

17. The method of claim 12, wherein forming the back gate comprises using the insulating layer for a selective etch stop.

18. The method of claim 12, wherein forming the contact comprises depositing the contact on the insulating layer.

19. The method of claim 12, wherein forming the field effect transistor comprising forming a via through the compound semiconductor region to reach the contact.

20. The method of claim 19, further comprising filling the via with a connecting conductor.

21. The method of claim 11, wherein forming the field effect transistor comprises forming a trench through the compound semiconductor region to reach the insulating layer.

22. The method of claim 21, further comprising providing a contact on the insulating layer in the trench.

23. The method of claim 22, further comprising forming a conducting connector that reaches the contact through the trench.

24. The method of claim 11, further comprising conducting electricity through the back gate through capacitive action with the body of the field effect transistor.

25. The method of claim 24, wherein forming the back gate comprises forming a contact that is insulated from the body of the field effect transistor by the insulating layer.

26. The method of claim 25, wherein forming the contact is performed before forming a source and a drain for the field effect transistor.

27. The method of claim 25, wherein forming the contact is performed after forming a source and a drain for the field effect transistor.

28. The method of claim 25, wherein forming the contact comprises etching through the compound semiconductor region to reach the insulating layer.

29. The method of claim 25, wherein forming the contact comprises epitaxially growing the contact over the compound semiconductor region before forming the insulating layer.

30. The method of claim 25, wherein forming the back gate comprises using the insulating layer for a selective etch stop.

31. The method of claim 25, wherein forming the contact comprises depositing the contact on the insulating layer.

32. The method of claim 25, wherein forming the field effect transistor comprising forming a via through the compound semiconductor region to reach the contact.

33. The method of claim 32, further comprising filling the via with a connecting conductor.

34. The method of claim 24, wherein forming the field effect transistor comprises forming a trench through the compound semiconductor region to reach the insulating layer.

35. The method of claim 34, further comprising providing a contact on the insulating layer in the trench.

36. The method of claim 35, further comprising forming a conducting connector that reaches the contact through the trench.

37. A hybrid semiconductor structure comprising:
a non-compound semiconductor region;
an insulating layer that overlies the non-compound semiconductor region;
a compound semiconductor field effect transistor having a body that overlies the insulating layer that overlies the non-compound semiconductor region;
an insulated back gate for the field effect transistor that is insulated from the body of the field effect transistor by the insulating layer and that includes a contact comprising metal and includes a connecting conductor that reaches the contact through the non-compound semiconductor region.

38. The device of claim 37, wherein the contact is positioned partly over the non-compound semiconductor region.

39. The device of claim 38, wherein the connecting conductor reaches the contact through a via in the non-compound semiconductor region.

40. The device of claim 39, wherein the contact is insulated from the body of the field effect transistor with the insulating layer.

41. The device of claim 40, wherein the connecting conductor reaches the contact through a trench that extends to the insulating layer.

42. The device of claim 37, wherein the field effect transistor is configured to have the back gate conduct electricity through capacitive action with the body of the field effect transistor.

43. The device of claim 42, wherein the contact is positioned partly over the non-compound semiconductor region.

44. The device of claim 43, wherein the connecting conductor reaches the contact through a via in the non-compound semiconductor region.

45. The device of claim 44, wherein the contact is insulated from the body of the field effect transistor with the insulating layer.

46. The device of claim 45, wherein the connecting conductor reaches the contact through a trench that extends to the insulating layer.

47. A method comprising:
forming a non-compound semiconductor region;
forming an insulating layer that overlies the non-compound semiconductor region;
forming a compound semiconductor region overlying the insulating layer; and
forming in the compound semiconductor region a compound semiconductor field effect transistor having a body that overlies the insulating layer and a back gate that is insulated from the body of the field effect transistor by the insulating layer and that includes a contact for the back gate that comprises metal.

48. The method of claim 47, wherein forming the back gate comprises forming the contact to be insulated from the body of the field effect transistor by the insulating layer.

49. The method of claim 48, wherein forming the contact is performed before forming a source and a drain for the field effect transistor.

50. The method of claim 48, wherein forming the contact is performed after forming a source and a drain for the field effect transistor.

51. The method of claim 48, wherein forming the contact comprises etching through the non-compound semiconductor region to reach the insulating layer.

52. The method of claim 48, wherein forming the contact comprises epitaxially growing the contact over the non-compound semiconductor region before forming the insulating layer.

53. The method of claim 48, wherein forming the back gate comprises using the insulating layer for a selective etch stop.

54. The method of claim 48, wherein forming the contact comprises depositing the contact on the insulating layer.

55. The method of claim 48, wherein forming the field effect transistor comprising forming a via through the non-compound semiconductor region to reach the contact.

56. The method of claim 55, further comprising filling the via with a connecting conductor.

57. The method of claim 47, wherein forming the field effect transistor comprises forming a trench through the non-compound semiconductor region to reach the insulating layer.

58. The method of claim 57, further comprising providing the contact on the insulating layer in the trench.

59. The method of claim 58, further comprising forming a conducting connector that reaches the contact through the trench.

60. The method of claim 47, further comprising conducting electricity through the back gate through capacitive action with the body of the field effect transistor.

61. The method of claim 60, further comprising insulating the contact from the body of the field effect transistor using the insulating layer.

62. The method of claim 61, wherein forming the contact is performed before forming a source and a drain for the field effect transistor.

63. The method of claim 61, wherein forming the contact is performed after forming a source and forming a drain for the field effect transistor.

64. The method of claim 61, wherein forming the contact comprises etching through the non-compound semiconductor region to reach the insulating layer.

65. The method of claim 61, wherein forming the contact comprises epitaxially growing the contact over the non-compound semiconductor region before forming the insulating layer.

66. The method of claim 61, wherein forming the back gate comprises using the insulating layer for a selective etch stop.

67. The method of claim 61, wherein forming the contact comprises depositing the contact on the insulating layer.

68. The method of claim 61, wherein forming the field effect transistor comprises forming a via through the non-compound semiconductor region to reach the contact.

69. The method of claim 68, further comprising filling the via with a connecting conductor.

70. The method of claim 60, wherein forming the field effect transistor comprises forming a trench through the non-compound semiconductor region to reach the insulating layer.

71. The method of claim 70, further comprising providing the contact on the insulating layer in the trench.

72. The method of claim 71, further comprising forming a conducting connector that reaches the contact through the trench.
